(19) United States
(12) Patent Application Publication
(10) Pub. No.: US 2014/0134823 A1
(43) Pub. Date: May 15, 2014

(54) HIGH-K PEROVSKITE MATERIALS AND METHODS OF MAKING AND USING THE SAME

(71) Applicants: Bryan C. Hendrix, Danbury, CT (US); Steven M. Bilodeau, Oxford, CT (US); Ing-Shin Barry Chen, Danbury, CT (US); Jeffrey F. Roeder, Brookfield, CT (US); Gregory T. Stauf, Branchburg, NJ (US)

(72) Inventors: Bryan C. Hendrix, Danbury, CT (US); Steven M. Bilodeau, Oxford, CT (US); Ing-Shin Barry Chen, Danbury, CT (US); Jeffrey F. Roeder, Brookfield, CT (US); Gregory T. Stauf, Branchburg, NJ (US)

(73) Assignee: ADVANCED TECHNOLOGY MATERIALS, INC., Danbury, CT (US)

(21) Appl. No.: 14/128,043

(22) PCT Filed: Jun. 19, 2012
(86) PCT No.: PCT/US2012/043153

§ 371 Date: Dec. 20, 2013

Related U.S. Application Data
(60) Provisional application No. 61/499,168, filed on Jun. 20, 2011.

(51) Int. Cl. H01L 49/02; H01L 27/108

(52) U.S. Cl. CPC H01L 28/55; H01L 27/108
USPC 438/396; 438/785

(57) ABSTRACT

High-k materials and devices, e.g., DRAM capacitors, and methods of making and using the same. Various methods of forming perovskite films are described, including methods in which perovskite material is deposited on the substrate by a pulsed vapor deposition process involving contacting of the substrate with perovskite material-forming metal precursors. In one such method, the process is carried out with doping or alloying of the perovskite material with a higher mobility and/or higher volatility metal species than the metal species in the perovskite material-forming metal precursors. In another method, the perovskite material is exposed to elevated temperature for sufficient time to crystallize or to enhance crystallization of the perovskite material, followed by growth of the perovskite material under pulsed vapor deposition conditions. Various perovskite compositions are described, including: (Sr, Pb)TiO₃; SrRuO₃ or SrTiO₃, doped with Zn, Cd or Hg; Sr(Sn,Ru)O₃; and Sr(Sn,Ti)O₃.

### FIELD

The present disclosure relates to relates to high-k materials and devices, and to methods of making and using the same.

### DESCRIPTION OF THE RELATED ART

In the continuing development of dynamic random access memory (DRAM) technology, atomic layer deposition (ALD) of thin film perovskite materials, such as strontium titanate (STO), strontium ruthenate (SRO), and barium strontium titanate (BST), will be a particular focus of all major DRAM manufacturers with high volume manufacturing (HVM) capability in coming years.

In such efforts, it will be necessary to deposit these perovskite films over very high aspect ratio structures (30:1 to 100:1) at minimum feature size for the node in question. ALD processes are desired for such applications in order to achieve requisite conformality, thickness control and composition control of the deposited perovskite films.

A significant problem in the application of ALD processes to the production of DRAM devices incorporating the above-identified perovskite materials is that with ALD, composition ratios between different metals need to be controlled by separate pulses because no two precursors transport in exactly the same way. If a predetermined ratio of precursors is delivered into the gas stream flowed to the deposition chamber, then the chemisorption rate and saturation of the surface will be different at the top and the bottom of the structure. If separate precursor pulses are utilized for each metal in the atomic layer deposition process, then the resulting deposited composition can be uniform over all parts of the structure, but fine composition adjustment, e.g., from 50.2 at % to 50.5 at %, is very difficult for a film that might take a few hundred precursor pulses to complete the deposition of the ALD film.

Another issue with such perovskite films is that they need to be fully crystallized in order to yield the best properties (high conductivity for SRO, high capacitance for STO and BST). The high deposition temperatures needed for in-situ deposition of crystalline films, however, can cause self-decomposition of the precursor in areas of the structure in which mass transport is greatest during the period of time that is required to fully saturate all parts of the structure. For this reason, it would be advantageous to provide compositions that crystallize more readily at lower deposition temperatures.

Currently, it is difficult to fully crystallize deposited films of SRO or STO with a thermal budget that is compatible with post-silicide processes. In order to maximize the dielectric constant of a high k perovskite, the grain size should be maximized. This in turn requires maximizing the long-range interactions that yield high k values. In order to achieve highly ordered perovskite films of the dielectric material, the dielectric can be deposited on a lattice-matched substrate of a similar structure. The highest order is achieved at the lowest temperature by nucleating and growing the crystals as the film is growing. This is because the metal-containing species have higher mobility on the surface, before they are covered with a capping layer. Nucleating the initial crystalline phase of materials such as SRO on normal plug or bottom electrode material (e.g., TiN, W, TaN, etc.) requires excessive temperatures if the nucleation is performed after deposition of the full thickness of the SRO film.

Deposition temperature at which crystallization occurs with growth is too high for most ALD precursors to remain intact. Some decomposition occurs in the inert environment of the precursor pulse. Such decomposition leads to thicker films on the regions of the capacitor structure where mass transport of the precursors is higher.

The foregoing underscores the substantial challenges of composition control in deep structures such as DRAM capacitors, and the difficulties of nucleating perovskite phases of materials such as SrTiO₃ under the low temperatures conditions most advantageously used for ALD.

Accordingly, new methods and materials are needed for providing high dielectric constant perovskite films of a crystalline and finely controlled compositional character, which can be readily formed at low deposition temperatures in the fabrication of DRAM and other microelectronic devices.

### SUMMARY

The present disclosure relates to relates to high-k materials and devices, and processes for making and using the same.

In one aspect, the disclosure relates to a method of forming a perovskite film, comprising depositing a perovskite material on a substrate by a pulsed vapor deposition process involving contacting of the substrate with perovskite material-forming metal precursors, wherein said process is carried out with doping or alloying of the perovskite material with a higher mobility and/or higher volatility metal species than the metal species in said perovskite material-forming metal precursors.

In another aspect, the disclosure relates to a perovskite composition comprising (Sr,Pb)RuO₃.

In a further aspect, the disclosure relates to a perovskite composition comprising a (Sr,Pb)RuO₃ material having deposited thereon a titanium-containing material selected from the group consisting of strontium titanate, barium strontium titanate, and lead strontium titanate.

A further aspect of the disclosure relates to a perovskite composition comprising (Sr, Pb)TiO₃.

A still further aspect of the disclosure relates to a perovskite composition comprising SrRuO₃ or SrTiO₃, doped with Zn, Cd or Hg.

Another aspect of the disclosure relates to a perovskite composition comprising Sr(Sn,Ru)O₃; and Sr(Sn,Ti)O₃.

Yet another aspect of the disclosure relates to a method of forming a crystallized perovskite material, comprising depositing a perovskite material in an amorphous state or a fine crystalline state on a substrate by a pulsed vapor deposition process involving contacting of the substrate with perovskite material-forming metal precursors, purging reactive species from the deposited perovskite material, and exposing the perovskite material to elevated temperature for sufficient time to crystallize or to enhance crystallization of the perovskite material.

In a further aspect, the disclosure relates to a method of fabricating a DRAM capacitor, comprising:

providing a bottom electrode;
depositing a layer of PbO on the bottom electrode;
depositing on the layer of PbO a B-site atomic species effective for nucleation of a perovskite material in the presence of PbO; and
depositing a perovskite material on the PbO layer having B-site atomic species thereon, by a pulsed vapor deposition process involving contacting of the substrate with perovskite material-forming metal precursors; and
depositing a top electrode on the perovskite material.

A still further aspect of the disclosure relates to a method of fabricating a DRAM capacitor, comprising:

providing a bottom electrode;
depositing a perovskite material on the bottom electrode by a vapor deposition process in which the perovskite material is doped or alloyed with PbO in its lattice structure;
increasing temperature and/or decreasing pressure to establish a process condition at which free PbO is volatile and PbO in the perovskite lattice structure is involatile;
removing volatile PbO; and
depositing a top electrode on the perovskite material.

Other aspects, features and embodiments of the disclosure will be more fully apparent from the ensuing description and appended claims.

### BRIEF DESCRIPTION OF THE DRAWINGS

FIG. 1 is a schematic cross-sectional view of a memory cell unit for a DRAM device, in which a high-k perovskite film of the present disclosure may be employed.

### DETAILED DESCRIPTION

The present disclosure relates to relates to high-k materials and devices, and to methods of making and using the same.

The present disclosure in one aspect relates to doping of perovskite films for increased crystallization, compositional control, and polarizability. In such aspect, the disclosure contemplates the use of a higher mobility and/or higher volatility metal ion to alloy or dope a perovskite film in order to achieve a self-limiting process and lower crystallization temperature. For example, Pb, Sn, Zn, Cd, Hg can be used for such purpose as dopant species in dielectric or conducting perovskites, and Bi can be used as a dopant species in conducting perovskites. Bismuth, however, is preferably avoided in the deposition of crystalline dielectric materials, since it can cause unwanted leakage in crystalline dielectric applications.

In an illustrative implementation in which a strontium ruthenate (SRO) film is formed by pulsed vapor deposition, in the fabrication of an SRO DRAM capacitor structure, a Pb precursor is pulsed in place of some of the Sr pulses in the alternating strontium/ruthenium train of vapor pulses utilized to form the high dielectric constant capacitor film. Such utilization of the lead precursor to dope the strontium ruthenate film achieves a lower crystallization temperature and reduces deposition temperature to a level at which premature decomposition around the top of the capacitor structure is minimized. The increased mobility of the resulting PbO in the film compared to SrO allows the crystallization of (Sr,Pb)RuO₃, also designated herein as “SPRO,” at a significantly lower temperature than the 400-600° C. temperature range that is characteristic of conventional chemical vapor deposition (CVD) of SRO. In addition, the increased mobility of excess PbO allows the film composition to be controlled by the volatility of the PbO.

In another aspect, a strontium titanate (STO) film can be deposited directly on the SPRO film with superior crystallization as a consequence of the templating of the STO film from the SPRO substrate layer. A further advantage of SPRO over SRO is that the lattice parameter of SPRO is increased by lead doping, in relation to SRO, thereby achieving improved lattice matching to STO, BST, and PST.

In another aspect, excess PbO inclusions can be provided in the SRO film, and these excess PbO inclusions can react with subsequently deposited STO to form a Pb-doped composition with a perfect A:B ratio of the crystal lattice A-sites and B-sites in the film.

Alternatively, additional Pb can be deposited with the STO to form (SrPb)TiO₃, also designated herein as “SPTO.” This approach has advantages over STO in three primary aspects: (i) the increased mobility of Pb will aid in crystallization of the lead-doped film material, (ii) the increased Curie point of the lead-doped dielectric film will increase the dielectric constant of the film material, and (iii) by controlling the partial pressure of the PbO in the deposition process or in a subsequent annealing step, the A:B ratio in the film is controlled to achieve a low leakage character.

While the foregoing discussion has been directed to various embodiments including Pb doping, it will be recognized that the generalized approaches of such embodiments readily extend to the use of other perovskite film dopant species.

Thus, other A-site dopants such as Zn, Cd, and Hg can be used in the same manner as described above for Pb.

B-site dopants such as Sn can be utilized to “tune” the lattice parameter relative to Ti or Ru. The addition of excess tin dioxide (SnO₂) can also be utilized to provide a B-site rich composition having lower leakage than A-site rich compositions of STO and BST.

In accordance with another aspect of the disclosure, rapid thermal annealing (RTA) is utilized to carry out vapor deposition crystallization with a low thermal budget. More specifically, such aspect of the disclosure relates to vapor deposition processes for forming perovskite films, in which the processes are carried out using ALD and pulsed (digital) CVD processes to separate reactive precursors from each other, as well as from reactive plasmas and other excited species. The precursors are thermally stable at the deposition temperature.

In accordance with this aspect of the disclosure, after a critical thickness of dielectric material has been deposited in an amorphous state or a very fine crystalline state, the reactive species (both metal and co-reactant) are purged from the wafer surface. A short high temperature exposure that is utilized to crystallize or enhance the crystallization of the deposited layer. The duration of the high temperature exposure and the time-temperature profile of such exposure can readily be determined within the skill of the art, based on the disclosure herein, by the simple expedient of varying time and temperature over respective ranges of their combination, to determine empirically a process envelope affording the improved crystallinity of the deposited material.

Subsequent pulsed deposition of the film will grow with the preferred crystal size and orientation that was established in the high temperature step.

Another aspect of the disclosure relates to PbO enhanced nucleation and composition control for perovskite dielectrics deposited by vapor deposition processes such as atomic layer deposition. Such aspect of the disclosure addresses the difficulty of compositional control in deep structures, e.g., DRAM capacitors, and concurrently addresses the difficulty of nucleation of perovskite phases of materials such as strontium titanate (STO) at the low temperatures used in atomic layer deposition. This aspect of the disclosure contemplates two specific approaches.

In a first approach, a DRAM capacitor is fabricated by a process including deposition of a first layer of PbO on a bottom electrode of the capacitor structure, in a pulsed vapor deposition process such as pulsed CVD or ALD. The temperature and pressure conditions of such PbO deposition are such that the PbO does not evaporate in the inert gas purge portions of the pulsed vapor deposition cycle. This first layer of PbO can be deposited to any suitable thickness, e.g., a thickness of from 0.5 Å to 15 Å. Next, a layer is deposited of a B-site atomic species such as titanium or zirconium, in order to nucleate the perovskite film utilizing the high mobility PbO. All subsequent pulses in the vapor deposition process can be conventional A-site or B-site oxides, e.g., SrO or TiO₂ if the perovskite is STO.

In a second approach, a DRAM capacitor is fabricated by a vapor deposition process. At the end of the process, the temperature can be increased and/or the pressure decreased to a condition at which free PbO is volatile, but PbO in the perovskite lattice is involatile. This condition can be readily determined by experiment. For example, conditions including pressure in a pressure region of 1-8 torr region exist in a 400-600° C. temperature region and may be employed to form a lead titanate perovskite material in an MOCVD process. Conditions for nucleating PbTiO₃ are disclosed for example in Chen, Ing-Shin, et al., Materials Research Society Symposium Proceedings (1999), 541 (Ferroelectric Thin Films VII), 375-380 (CAPLUS database), and in Aratani, Masanori, et al., Japanese Journal of Applied Physics, Part 2: Letters (2001), 40(4A), L343-L345, CAPLUS database.

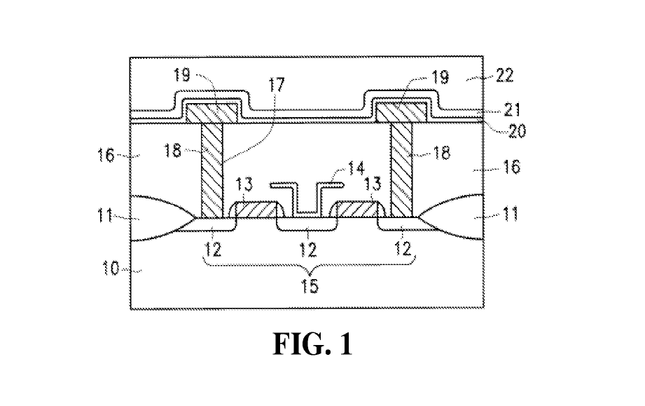

FIG. 1 is a schematic cross-sectional view of a memory cell unit for a DRAM device, according to one embodiment of the present disclosure, in which a high-k perovskite dielectric material of the present disclosure may be employed as a capacitor material. The DRAM device shown in FIG. 1 includes field oxide layer 11, poly gate layer 13, source/drain regions 12 and word line 14 of metal oxide semiconductor transistor 15. The device is fabricated on a substrate 10, which may be formed of silicon or other suitable substrate material. The device structure includes oxide layer 16, and contact openings 17 filled with conductive plugs 18 of suitable conductive material such as tungsten.

Conductive layer 19 deposited over the plugs 18 forms a bottom electrode of the capacitor, on which is deposited the dielectric layer 20 of a perovskite material of the present disclosure. A conductive layer 21 is deposited over the dielectric layer 20 as the top electrode of the capacitor structure. Interlevel dielectric layer 22 is formed over the top electrode layer 21.

The present disclosure contemplates a wide variety of aspects, features and embodiments.

In one aspect, the disclosure relates to a method of forming a perovskite film, comprising depositing a perovskite material on a substrate by a pulsed vapor deposition process involving contacting of the substrate with perovskite material-forming metal precursors, wherein such process is carried out with doping or alloying of the perovskite material with a higher mobility and/or higher volatility metal species than the metal species in the perovskite material-forming metal precursors.

The higher mobility and/or higher volatility metal species in such method may comprise a metal species selected from the group consisting of Pb, Sn, Zn, Cd, Hg, Bi, and oxides thereof. In a specific implementation, the perovskite material may comprise a dielectric or conducting perovskite, and the higher mobility and/or higher volatility metal species comprises a metal species selected from the group consisting of Pb, Sn, Zn, Cd, Hg, and oxides thereof. As another example, in the instance in which the perovskite material comprises a conducting perovskite, the higher mobility and/or higher volatility metal species can comprise bismuth or a bismuth oxide. In a still further embodiment, wherein the perovskite material comprises a crystalline dielectric perovskite, the higher mobility and/or higher volatility metal species may be constituted as not comprising bismuth.

In yet another embodiment of the method above described, the perovskite material doped with the higher mobility and/or higher volatility metal species has a lower crystallization temperature than a corresponding perovskite material undoped with the higher mobility and/or higher volatility metal species.

The perovskite material in such method may be of any suitable type. In one embodiment, the perovskite material comprises strontium ruthenate and the higher mobility and/or higher volatility metal species comprises Pb. The method in such instance may further comprise depositing strontium titanate, barium strontium titanate, or lead strontium titanate on the perovskite material comprising strontium ruthenate and doped or alloyed with Pb. In another embodiment, the perovskite material comprises strontium titanate and the higher mobility and/or higher volatility metal species comprises Pb.

In still other embodiments of the method broadly described above, the higher mobility and/or higher volatility metal species comprises Zn, Cd, Hg, or Sn. When the higher mobility and/or higher volatility metal species comprises Sn, the perovskite material can comprise titanium or ruthenium, in specific embodiments. In a specific embodiment, the higher mobility and/or higher volatility metal species comprises SnO₂; in such instance, the perovskite material may for example comprise strontium titanate, or barium strontium titanate.

A further aspect of the disclosure relates to a perovskite composition comprising (Sr,Pb)RuO₃.

Yet another aspect of the disclosure relates to a perovskite composition comprising a (Sr,Pb)RuO₃ material having deposited thereon a titanium-containing material selected from the group consisting of strontium titanate, barium strontium titanate, and lead strontium titanate.

A further aspect of the disclosure relates to a perovskite composition comprising (Sr, Pb)TiO₃.

A further embodiment of the disclosure relates to a perovskite composition comprising SrRuO₃ or SrTiO₃, doped with Zn, Cd or Hg. Yet another embodiment of the disclosure relates to a perovskite composition comprising Sr(Sn,Ru)O₃ or Sr(Sn,Ti)O₃.

Another method aspect of the disclosure relates to a method of forming a crystallized perovskite material, comprising depositing a perovskite material in an amorphous state or a fine crystalline state on a substrate by a pulsed vapor deposition process involving contacting of the substrate with perovskite material-forming metal precursors, purging reactive species from the deposited perovskite material, and exposing the perovskite material to elevated temperature for sufficient time to crystallize or to enhance crystallization of the perovskite material. The method may further comprise growing the perovskite material under pulsed vapor deposition conditions after such exposing.

In another method aspect, the disclosure relates to a method of fabricating a DRAM capacitor, comprising:

providing a bottom electrode;
depositing a layer of PbO on the bottom electrode;
depositing on the layer of PbO a B-site atomic species effective for nucleation of a perovskite material in the presence of PbO; and
depositing a perovskite material on the PbO layer having B-site atomic species thereon, by a pulsed vapor deposition process involving contacting of the substrate with perovskite material-forming metal precursors; and
depositing a top electrode on the perovskite material.

In such method, the layer of PbO can be formed by a pulsed vapor deposition process, such as chemical vapor deposition or atomic layer deposition.

The method in another implementation may be carried out so that the PbO layer is deposited to a thickness in a range of from 0.5 Å to 15 Å.

In other embodiments of the method, the B-site atomic species comprises titanium or zirconium. The perovskite material in a further embodiment comprises strontium titanate.

A further aspect of the disclosure relates to a method of fabricating a DRAM capacitor, comprising:

providing a bottom electrode;
depositing a perovskite material on the bottom electrode by a vapor deposition process in which the perovskite material is doped or alloyed with PbO in its lattice structure;
increasing temperature and/or decreasing pressure to establish a process condition at which free PbO is volatile and PbO in the perovskite lattice structure is involatile;
removing volatile PbO; and
depositing a top electrode on the perovskite material.

Such method may be carried out in one embodiment, wherein the perovskite material doped or alloyed with PbO in its lattice structure comprises lead titanate. In another embodiment of such method, the process condition at which free PbO is volatile and PbO in the perovskite lattice structure is involatile comprises a pressure in a range of from 1 to 8 torr and a temperature in a range of from 400 to 600° C. Lower temperatures can be used if the pressure is lowered; see Bosak, et al., JPhysIV, 11 Pr3, p93.

The various approaches described herein for formation of high dielectric constant perovskite films can be utilized in a suitable compatible combinations, to achieve perovskite films of superior crystallinity, compositional character and polarizability, utilizing processes for achieving enhanced nucleation and compositional control with low thermal budgets. It therefore seen that the approaches of the invention in various embodiments thereof can be utilized to achieve high-volume manufacturing (HBM) production of DRAM microelectronic devices by pulsed vapor deposition techniques for high k films of materials such as strontium titanate, strontium ruthenate, and barium strontium titanate.

While the disclosure has been has been set forth herein in reference to specific aspects, features and illustrative embodiments of the invention, it will be appreciated that the utility of the disclosure is not thus limited, but rather extends to and encompasses numerous other variations, modifications and alternative embodiments, as will suggest themselves to those of ordinary skill in the field of the present disclosure, based on the description herein. Correspondingly, the invention as hereinafter claimed is intended to be broadly construed and interpreted, as including all such variations, modifications and alternative embodiments, within its spirit and scope.

1. A method of forming a perovskite film, comprising depositing a perovskite material on a substrate by a pulsed vapor deposition process involving contacting of the substrate with perovskite material-forming metal precursors, wherein said process is carried out with doping or alloying of the perovskite material with a higher mobility and/or higher volatility metal species than the metal species in said perovskite material-forming metal precursors.

2. The method of claim 1, wherein the higher mobility and/or higher volatility metal species comprises a metal species selected from the group consisting of Pb, Sn, Zn, Cd, Hg, Bi, and oxides thereof.

3. The method of claim 1, wherein the perovskite material comprises a dielectric or conducting perovskite, and the higher mobility and/or higher volatility metal species comprises a metal species selected from the group consisting of Pb, Sn, Zn, Cd, Hg, and oxides thereof.

4. The method of claim 1, wherein the perovskite material comprises a conducting perovskite, and the higher mobility and/or higher volatility metal species comprises bismuth or a bismuth oxide.

5. The method of claim 1, wherein the perovskite material comprises a crystalline dielectric perovskite, and the higher mobility and/or higher volatility metal species does not comprise bismuth.

6. The method of claim 1, wherein the perovskite material doped with the higher mobility and/or higher volatility metal species has a lower crystallization temperature than a corresponding perovskite material undoped with the higher mobility and/or higher volatility metal species.

7. The method of claim 1, wherein the perovskite material comprises strontium ruthenate and the higher mobility and/or higher volatility metal species comprises Pb.

8. The method of claim 7, further comprising depositing strontium titanate, barium strontium titanate, or lead strontium titanate on the perovskite material comprising strontium ruthenate and doped or alloyed with Pb.

9. The method of claim 8, wherein strontium titanate is deposited on the perovskite material comprising strontium ruthenate and doped or alloyed with Pb.

10. The method of claim 8, wherein barium strontium titanate is deposited on the perovskite material comprising strontium ruthenate and doped or alloyed with Pb.

11. The method of claim 8, wherein lead strontium titanate is deposited on the perovskite material comprising strontium ruthenate and doped or alloyed with Pb.

12. The method of claim 1, wherein the perovskite material comprises strontium titanate and the higher mobility and/or higher volatility metal species comprises Pb.

13-19. (canceled)

20. The method of claim 19, wherein the perovskite material comprises strontium titanate or barium strontium titanate.

21-22. (canceled)

23. A perovskite composition, selected from the group consisting of:
(i) perovskite compositions comprising a (Sr,Pb)RuO₃ material having deposited thereon a titanium-containing material selected from the group consisting of strontium titanate, barium strontium titanate, and lead strontium titanate;
(ii) perovskite compositions comprising SrRuO₃ doped with Zn, Cd, or Hg; and
(iii) perovskite compositions comprising SrTiO₃ doped with Hg.

24-28. (canceled)

29. The perovskite composition of claim 23, comprising SrRuO₃.

30-35. (canceled)

36. A method of forming a crystallized perovskite material, comprising depositing a perovskite material in an amorphous state or a fine crystalline state on a substrate by a pulsed vapor deposition process involving contacting of the substrate with perovskite material-forming metal precursors, purging reactive species from the deposited perovskite material, and exposing the perovskite material to elevated temperature for sufficient time to crystallize or to enhance crystallization of the perovskite material.

37. The method of claim 36, further comprising growing the perovskite material under pulsed vapor deposition conditions after said exposing.

38. A method of fabricating a DRAM capacitor, comprising:
providing a bottom electrode;
forming perovskite material on the bottom electrode; and
depositing a top electrode on the perovskite material,
wherein formation of perovskite material on the bottom electrode comprises one of process (A) and (B):
process (A):
depositing a layer of PbO on the bottom electrode;
depositing on the layer of PbO a B-site atomic species effective for nucleation of a perovskite material in the presence of PbO; and
depositing a perovskite material on the PbO layer having B-site atomic species thereon, by a pulsed vapor deposition process involving contacting of the substrate with perovskite material-forming metal precursors; and
process (B):
depositing a perovskite material on the bottom electrode by a vapor deposition process in which the perovskite material is doped or alloyed with PbO in its lattice structure;
increasing temperature and/or decreasing pressure to establish a process condition at which free PbO is volatile and PbO in the perovskite lattice structure is involatile; and
removing volatile PbO.

39. The method of claim 38 comprising process (A), wherein the layer of PbO is formed by a pulsed vapor deposition process, and wherein the B-site atomic species comprises titanium or zirconium.

40-47. (canceled)

48. The method of claim 38 comprising process (B), wherein the process condition at which free PbO is volatile and PbO in the perovskite lattice structure is involatile comprises a pressure in a range of from 1 to 8 torr and a temperature in a range of from 400 to 600° C.
